(19) United States
(12) Patent Application Publication
(10) Pub. No.: US 2026/0223649 A1
(43) Pub. Date: Jul. 30, 2026

(54) MANUFACTURING METHOD OF SEMICONDUCTOR STRUCTURE

(71) Applicant: Winbond Electronics Corp., Taichung City (TW)

(72) Inventors: Jia-Wun Wu, Kaohsiung (TW); Pin-Hung Chen, Tainan (TW)

(73) Assignee: Winbond Electronics Corp., Taichung City (TW)

(21) Appl. No.: 19/257,456

(22) Filed: Jul. 1, 2025

(30) Foreign Application Priority Data
Jan. 24, 2025 (TW) 114103479

(51) Int. Cl. H01L 21/324; H01L 21/306; H01L 21/3213

(52) U.S. Cl. CPC H10P 95/90; H10P 50/644; H10P 50/667

(57) ABSTRACT

A manufacturing method of a semiconductor structure is provided. The manufacturing method includes the following steps. A gate structure is formed on a silicon substrate. Doped regions are formed in the silicon substrate on two sides of the gate structure. A dielectric layer is formed on the silicon substrate to cover the gate structure and the doped regions. Holes are formed in the dielectric layer to expose the doped regions, wherein a lower region of each of the holes is located in the doped region. An undoped silicon layer is formed in the lower region of each of the holes, wherein a size of silicon grains of the undoped silicon layer is smaller than that of the silicon substrate. A metal layer is formed on the undoped silicon layer. A heat treatment is performed to transform the metal layer and the undoped silicon layer into a metal silicide layer.

### CROSS-REFERENCE TO RELATED APPLICATION

This application claims the priority benefit of Taiwan application serial no. 114103479, filed on Jan. 24, 2025. The entirety of the above-mentioned patent application is hereby incorporated by reference herein and made a part of this specification.

### BACKGROUND

### Technical Field

The present invention relates to a manufacturing method of a semiconductor structure, and in particular to a manufacturing method of a semiconductor structure in which a metal silicide layer is formed on two sides of a gate structure.

### Description of Related Art

In the semiconductor process, after forming the transistor, a dielectric layer covering the transistor is formed on the silicon substrate, and an etching process is performed to form contact holes in the dielectric layer that expose the source region and the drain region of the transistor. Afterwards, the contact holes are filled with a conductive layer to form contacts. In addition, in order to reduce the resistance value at the source region and the drain region, a metal silicide layer is formed at the source region and the drain region exposed by the contact holes before filling the conductive layer.

In order to make the contact holes to be able to accurately expose the source region and the drain region, the source region and the drain region are over-etched during the etching process. As a result, when the metal silicide layer is formed, the metal silicide may diffuse into the silicon substrate around the source region and the drain region, causing the electrical properties of the device to be affected.

### SUMMARY

The present invention provides a manufacturing method of a semiconductor structure, which may prevent the metal silicide from diffusing into the silicon substrate around the source region and the drain region during forming the metal silicide layer.

The manufacturing method of the semiconductor structure of the present invention comprises the following steps. A gate structure is formed on a silicon substrate. Doped regions are formed in the silicon substrate on two sides of the gate structure. A dielectric layer is formed on the silicon substrate to cover the gate structure and the doped regions. Holes are formed in the dielectric layer to expose the doped regions, wherein a lower region of each of the holes is located in the doped region. An undoped silicon layer is formed in the lower region of each of the holes, wherein a size of silicon grains of the undoped silicon layer is smaller than a size of silicon grains of the silicon substrate. A metal layer is formed on the undoped silicon layer. A thermal treatment is performed to transform the metal layer and the undoped silicon layer into a metal silicide layer.

Based on the above, in the manufacturing method of the semiconductor structure of the present invention, before the metal silicide process, an undoped silicon material layer with the size of silicon grains is smaller than that of the silicon substrate is formed on the doped regions, thereby preventing the metal silicide from diffusing into the silicon substrate around the doped regions during the metal silicide process.

### BRIEF DESCRIPTION OF THE DRAWINGS

FIGS. 1A to 1H are schematic cross-sectional views of the manufacturing method of the semiconductor structure according to an embodiment of the present invention.

### DESCRIPTION OF THE EMBODIMENTS

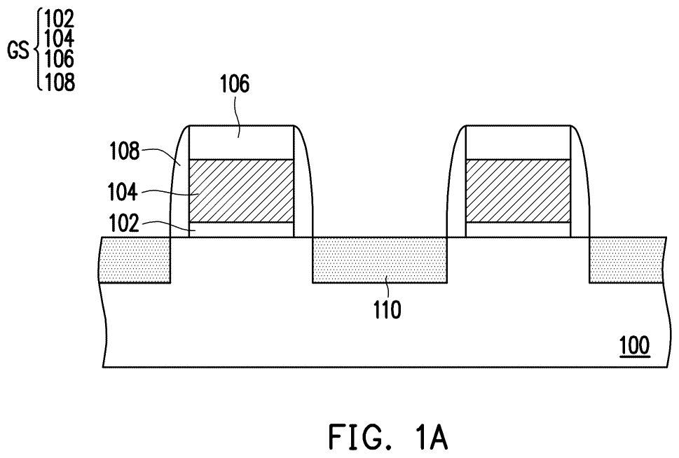

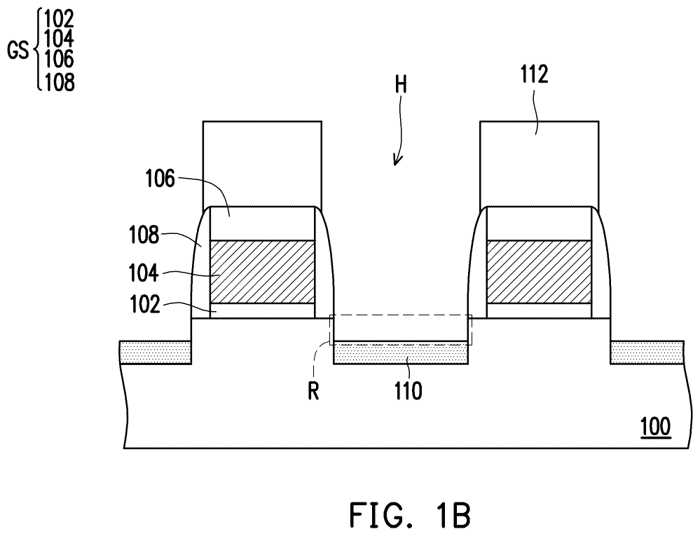

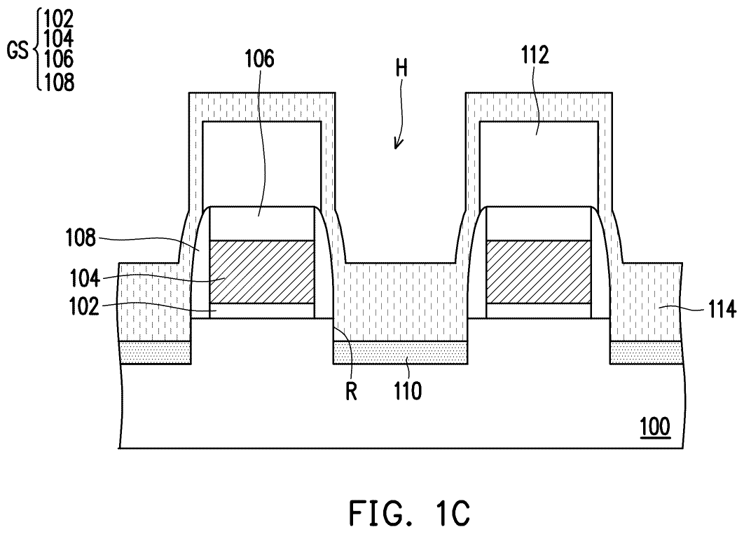

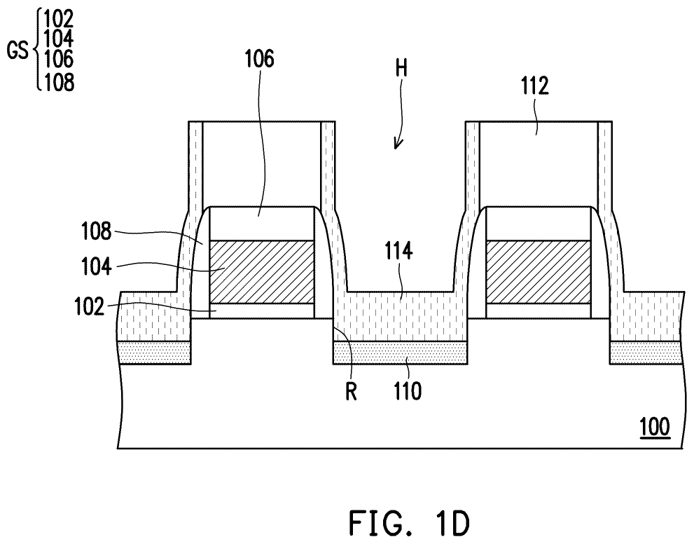

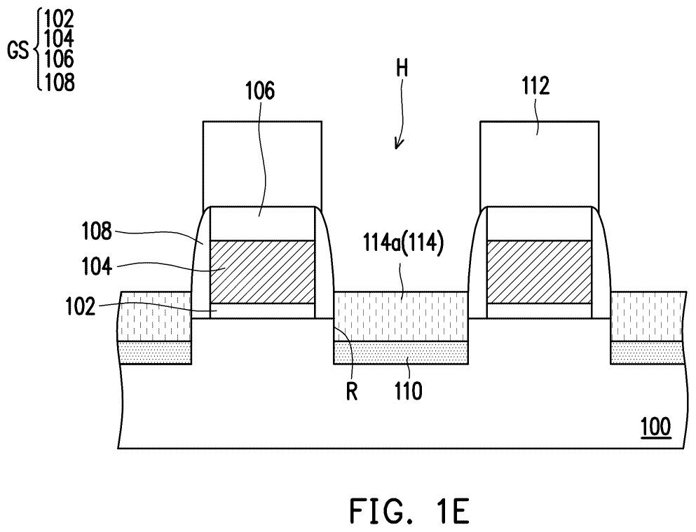

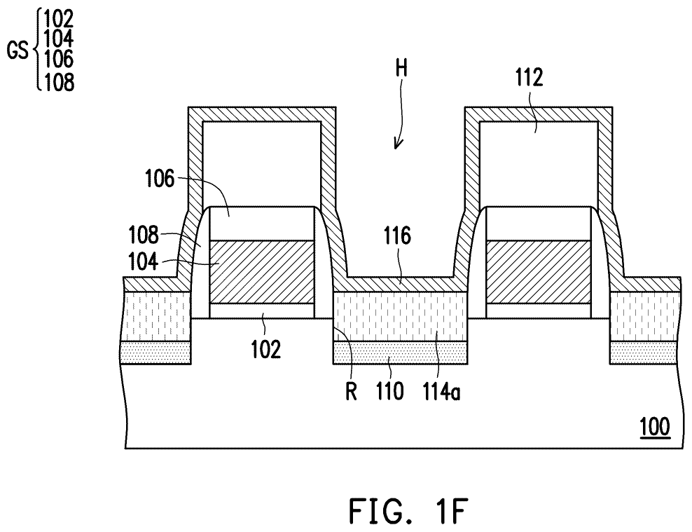

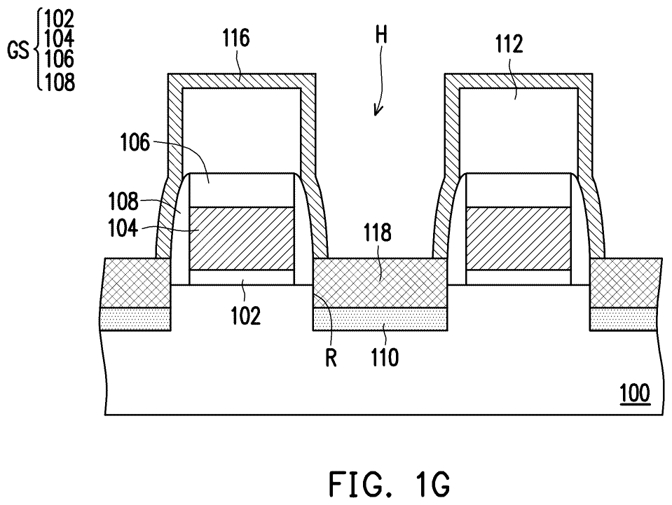

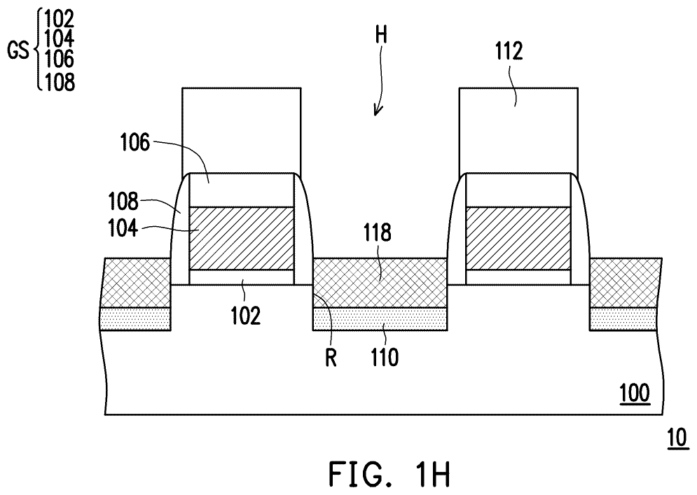

FIGS. 1A to 1H are schematic cross-sectional views of the manufacturing method of the semiconductor structure according to an embodiment of the present invention. The manufacturing method of the present embodiment may prevent the metal silicide from diffusing into the silicon substrate around the source region and the drain region during forming the metal silicide layer, thereby avoiding the leakage current. The manufacturing method of the present embodiment will be described in detail below.

Referring to FIG. 1A, a silicon substrate 100 is provided. The material of the silicon substrate 100 is, for example, single crystal silicon. The silicon substrate 100 is, for example, a silicon wafer. Next, a gate structure GS is formed on the silicon substrate 100. The gate structure GS includes a gate dielectric layer 102, a gate 104, and a capping layer 106 sequentially formed on the silicon substrate 100, and a spacer 108 formed on the sidewall of the gate 104, but the present invention is not limited thereto. The material of the gate dielectric layer 102 is, for example, silicon oxide. The material of the gate is, for example, polysilicon. The material of the capping layer 106 and the spacer 108 is, for example, silicon nitride. The forming method of the gate structure GS is well known to those skilled in the art and will not be further described herein.

After the gate structure GS is formed, doped regions 110 are formed in the silicon substrate 100 on two sides of the gate structure GS. The doped regions 110 are formed by, for example, performing an ion implantation process using the gate structure GS as a mask. The gate structure GS and the doped regions 110 may constitute a transistor, wherein the doped regions 110 may serve as the source region and the drain region of the transistor.

Referring to FIG. 1B, a dielectric layer 112 is formed on the silicon substrate 100 to cover the gate structure GS and the doped regions 110. The material of the dielectric layer 112 is, for example, silicon oxide. The dielectric layer 112 may serve as an inter-layer dielectric (ILD) layer. Next, an etching process is performed to form holes H in the dielectric layer 112. The holes H expose the doped regions 110. The holes H are used to form contacts in contact with the source region and drain region of the transistor. Therefore, the hole H may be called a contact hole.

In detail, the etching process may be performed using a patterned photoresist layer (not shown) and the spacer 108 as an etching mask. In addition, in order to ensure that the holes H may expose the doped regions 110 completely, the doped regions 110 may be over-etched to prevent the dielectric layer 112 from remaining on the doped regions 110. As a result, the lower region R of the hole H may be located in the doped region 110. That is, the bottom surface of the contact hole, the hole H, is lower than the top surface of the silicon substrate 100.

Referring to FIG. 1C, an undoped silicon material layer 114 is formed on the dielectric layer 112, and the undoped silicon material layer 114 fills into the holes H. The size of the silicon grains of the undoped silicon material layer 114 must be smaller than the size of the silicon grains of the silicon substrate 100. Therefore, the material of the undoped silicon material layer 114 is, for example, amorphous silicon or polysilicon. The undoped silicon material layer 114 may be formed by, for example, a physical vapor deposition (PVD) process.

In this step, the undoped silicon material layer 114 fills the lower region R of the hole H, and the top surface of the undoped silicon material layer 114 in the hole H is higher than the top surface of the silicon substrate 100. The top surface of the undoped silicon material layer 114 in the hole H is not higher than the top surface of the gate 104.

Referring to FIG. 1D, an anisotropic etching process is performed to remove the undoped silicon material layer 114 on the top surface of the dielectric layer 112. During removing the undoped silicon material layer 114 on the top surface of the dielectric layer 112, the undoped silicon material layer 114 in the holes H is also partially removed, but the undoped silicon material layer 114 is still remained in the lower region R of the hole H. In addition, the undoped silicon material layer 114 is remained on the sidewall of the hole H, and the thickness of the undoped silicon material layer 114 remaining on the sidewall of the hole H is smaller than the thickness of the undoped silicon material layer 114 remaining in the lower part of the hole H.

After removing the undoped silicon material layer 114 on the top surface of the dielectric layer 112, the top surface of the undoped silicon material layer 114 located in the lower part of the hole H is still higher than the top surface of the silicon substrate 100, but the present invention is not limited thereto. After removing the undoped silicon material layer 114 on the top surface of the dielectric layer 112, the top surface of the lower undoped silicon material layer 114 located in the lower part of the hole H may be coplanar with the top surface of the silicon substrate 100, or lower than the top surface of the silicon substrate 100.

Referring to FIG. 1E, the undoped silicon material layer 114 on the sidewall of the hole H is removed to form an undoped silicon layer 114a on the doped regions 110. The method for removing the undoped silicon material layer 114 on the sidewall of the hole H is, for example, performing a wet etching process. In the wet etching process, the etchant used is, for example, diluted hydrofluoric acid (DHF).

In this step, during removing the undoped silicon material layer 114 on the sidewall of the hole H, the undoped silicon material layer 114 located in the lower part of the hole H is also partially removed at the same time, but the undoped silicon material layer 114 is still remained in the lower portion R of the hole H. Since the thickness of the undoped silicon material layer 114 on the sidewall of hole H is less than the thickness of the undoped silicon material layer 114 in the lower part of the hole H, after removing the undoped silicon material layer 114 on the sidewall of hole H, the undoped silicon material layer 114 (the undoped silicon layer 114a) may be remained in the lower region R of the hole H.

The top surface of the undoped silicon layer 114a remaining in the lower part of the hole H is higher than the top surface of the silicon substrate 100, but the present invention is not limited thereto. The top surface of the lower undoped silicon layer 114 remaining in the lower part of the hole H may be coplanar with the top surface of the silicon substrate 100, or lower than the top surface of the silicon substrate 100.

Referring to FIG. 1F, a metal material layer 116 is conformally formed on the silicon substrate 100. The metal material layer 116 covers the top surface of the dielectric layer 112, the sidewall of the holes H and the top surface of the undoped silicon layer 114a. The metal material layer 116 is used to react with the undoped silicon layer 114a in the subsequent process to form a metal silicide layer. The material of the metal material layer 116 is, for example, cobalt (Co), but the present invention is not limited thereto.

Referring to FIG. 1G, a thermal treatment is performed to react the metal material layer 116 on the undoped silicon layer 114a with the undoped silicon layer 114a. During the reaction, metal diffuses from the metal material layer 116 into the undoped silicon layer 114a to react with silicon to form metal silicide. Therefore, after the thermal treatment, the metal material layer 116 and the undoped silicon layer 114a may be completely transformed into a metal silicide layer 118. The metal silicide layer 118 formed at the doped regions 110 may be used to reduce the resistance value at the source region and the drain region of the transistor.

Since the top surface of the undoped silicon layer 114a is higher than the top surface of the silicon substrate 100, the top surface of the formed metal silicide layer 118 is higher than the top surface of the silicon substrate 100. When the top surface of the undoped silicon layer 114a is not higher than the top surface of the silicon substrate 100, the formed metal silicide layer 118 is only located in the lower region R of the hole H.

In addition, the size of the silicon grains of the undoped silicon layer 114a is smaller than the size of the silicon grains of the silicon substrate 100, so the metal material layer 116 reacts quickly with the undoped silicon layer 114a during the thermal treatment. Furthermore, even if the top surface of the undoped silicon layer 114a is lower than the top surface of the silicon substrate 100 before the thermal treatment so that the lower region R of the hole H exposes the silicon substrate 100, during the thermal treatment, the metal material layer 118 will preferentially react with the undoped silicon layer 114a, rather than react with the silicon substrate 100. On the other hand, the temperature of the thermal treatment may also be lower, reducing energy consumption. In this way, the problem of metal silicide diffusing into the silicon substrate 100 is avoided.

Referring to FIG. 1H, the unreacted metal material layer 116 on the top surface of the dielectric layer 112 and on the sidewall of holes H is removed. In this way, the semiconductor structure 10 of the present embodiment is formed. The method for removing the unreacted metal material layer 116 is, for example, performing a wet etching process. In the wet etching process, the etchant used is, for example, sulfuric acid.

In the manufacturing method of the semiconductor structure 10, since the undoped silicon layer 114a having the size of the silicon grains smaller than that of the silicon substrate 100 is formed on the doped regions 110, during the metal silicide process for forming the metal silicide layer 118, the metal silicide may be prevented from diffusing into the silicon substrate 100 around the doped regions 110, thereby preventing the formed device from generating leakage current during operation.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a semiconductor structure, comprising:
forming a gate structure on a silicon substrate;
forming doped regions in the silicon substrate on two sides of the gate structure;
forming a dielectric layer on the silicon substrate to cover the gate structure and the doped regions;
forming holes in the dielectric layer to expose the doped regions, wherein a lower region of each of the holes is located in the doped region;
forming an undoped silicon layer in the lower region of each of the holes, wherein a size of silicon grains of the undoped silicon layer is smaller than a size of silicon grains of the silicon substrate;
forming a metal layer on the undoped silicon layer; and
performing a thermal treatment to transform the metal layer and the undoped silicon layer into a metal silicide layer.

2. The manufacturing method of claim 1, wherein a material of the silicon substrate comprises single crystal silicon.

3. The manufacturing method of claim 2, wherein a material of the undoped silicon layer comprises amorphous silicon or polysilicon.

4. The manufacturing method of claim 1, wherein a top surface of the undoped silicon layer is not lower than a top surface of the silicon substrate.

5. The manufacturing method of claim 4, wherein the top surface of the undoped silicon layer is higher than the top surface of the silicon substrate.

6. The manufacturing method of claim 1, wherein a method for forming the undoped silicon layer comprises:
forming an undoped silicon material layer on the dielectric layer, wherein the undoped silicon material layer at least fills the lower region of each of the holes;
performing an anisotropic etching process to remove the undoped silicon material layer on a top surface of the dielectric layer; and
removing the undoped silicon material layer on a sidewall of each of the holes.

7. The manufacturing method of claim 6, wherein after the anisotropic etching process and before removing the undoped silicon material layer, a thickness of the undoped silicon material layer remaining on a sidewall of the hole is smaller than a thickness of the undoped silicon material layer remaining in a lower part of the hole.

8. The manufacturing method of claim 6, wherein after the anisotropic etching process, a top surface of the undoped silicon material layer located in a lower part of the hole is higher than a top surface of the silicon substrate.

9. The manufacturing method of claim 6, wherein a method for removing the undoped silicon material layer on the sidewall of each of the holes comprises performing a wet etching process.

10. The manufacturing method of claim 9, wherein an etchant of the wet etching process comprises diluted hydrofluoric acid.

11. The manufacturing method of claim 1, wherein a method for forming the metal layer comprises:
conformally forming a metal material layer on the silicon substrate, wherein the metal material layer covers a top surface of the dielectric layer, a sidewall of each of the holes and a top surface of the undoped silicon layer.

12. The manufacturing method of claim 11, wherein a material of the metal material layer comprises cobalt.

13. The manufacturing method of claim 11, wherein after the thermal treatment, the metal material layer and the undoped silicon layer are completely transformed into the metal silicide layer.

14. The manufacturing method of claim 11, further comprising removing the metal material layer on the top surface of the dielectric layer and on the sidewall of each of the holes after forming the metal silicide layer.

15. The manufacturing method of claim 14, wherein a method for removing the metal material layer on the top surface of the dielectric layer and on the sidewall of each of the holes comprises performing a wet etching process.

16. The manufacturing method of claim 15, wherein an etchant of the wet etching process comprises sulfuric acid.

17. The manufacturing method of claim 1, wherein the silicon substrate comprises silicon wafer.

18. The manufacturing method of claim 1, wherein a method for forming the holes comprises performing a etching process on the dielectric layer and the doped regions.

19. The manufacturing method of claim 1, wherein a bottom surface of the hole is lower than a top surface of the silicon substrate.
